(19) United States
(12) Patent Application Publication
(10) Pub. No.: US 2003/0026143 A1
(43) Pub. Date: Feb. 6, 2003

(54) Method for automating the construction of data stores for storing complex relational and hierarchical data and optimising the access and update of the data therein method for defining look and feel of a user interface obviating the requirement to write programming language code

(76) Inventor: Declan M. Brennan, Dublin (IE)

Correspondence Address: John Whelehan, 103-2609 Westview Drive, Unit 245, North Vancouver, BC, V7N 4N2, CA

(21) Appl. No.: 10/213,207

(22) Filed: Aug. 5, 2002

Related U.S. Application Data
(60) Provisional application No. 60/309,587, filed on Aug. 3, 2001.

(51) Int. Cl. G11C 29/00

(52) U.S. Cl. 365/200

(57) ABSTRACT

A method for automatically assembling a data store 5 implementation from an abstract data model and automatically assembling data-sets indicating which parts of the data store 5 are required for each purpose (including data entry and reporting) and automatically generating data store 5 specific code for each such purpose optimized to minimize server loading and network traffic.

### CROSS REFERENCE TO RELATED ACTIONS

This application claims the benefit of PPA Ser. No. 60/309,587

### FEDERALLY SPONSORED RESEARCH

Not Applicable

### SEQUENCE LISTING OR PROGRAM

Not Applicable

### FIELD OF THE INVENTION

The present invention pertains to the field of data management applications including conventional applications running on a computer and web applications deployed over a network such as an intranet or the internet. Such applications will utilize a data store which may comprise a SQL database or an XML repository. The invention automates many aspects of the production and operation of such applications.

### BACKGROUND OF THE INVENTION

Production of optimized data stores currently requires the skilled expertise of database designers and database administrators. In multiple tier, (also referred to as n-tier in the art) data management applications, custom programming code is commonly required to provide optimal access to the data store for each utility of the application, for example producing a data entry screen or a report. Such programming code is normally produced by software developers. This is expensive, time consuming and prone to human error. This invention describes a method which includes automatically building and maintaining an optimized data store and automatically building and maintaining optimized programming code to allow access to and update of the data in the data store. It is a feature of the invention that the automation described above allows most of a data management application to be assembled by graphic designers and business experts at reduced cost and with reduced errors.

### SUMMARY OF THE INVENTION

The invention comprises a method for automatically building and maintaining an optimized data store which includes means for the definition of abstract objects and their relationships, means for realization of the abstract description in a physical data store, a user screen designer that automatically maintains data set descriptions and the actual user screen design. The invention further comprises a method for automatically building and maintaining optimized programming code to allow access to and update of the data in the data store which includes means for the automatic generation of code to generate data store specific code for each data set while optimizing server performance and minimizing network traffic, a client server protocol that allows optimized access to the actions available for a data set and a mechanism for explicitly defining data set descriptions where necessary, whereby these data sets can allow access to specific portions of the data store from custom code event handlers.

### BRIEF DESCRIPTION OF THE DRAWINGS

The present invention is illustrated by way of example and not limitation in the figures of the accompanying drawings, in which like references indicate similar elements and in which:

FIG. 1 shows an overview of the invention in a network environment

FIG. 2 shows an example of a simple abstract data model

FIG. 3 shows an example of a realization of the example depicted in FIG. 2 in a relational database data store

FIG. 4 shows an example of automatically generated code for a HTML data page screen

FIG. 5 shows an example of automatically generated data set description for the screen referenced in FIG. 4

FIG. 6 shows a partial list of actions available for a data-set

FIG. 7 shows an example of the client server protocol flowchart depicting the server response to client requests

FIG. 8 shows an example of a request for the first person (in default order)

FIG. 9 shows an example of the response to the request in FIG. 8

FIG. 10 shows an example of a request to change some data from FIG. 9

FIG. 11 shows an example of a response that indicates a validation failure

FIG. 12 shows an example of an explicit data-set used to modify a person's name

FIG. 13 shows an example of a custom event handler used to modify a person's name

FIG. 14 shows the attributes and elements that may be in a data set request

FIG. 15 shows the actions that may be in a data set request

FIG. 16 shows the attributes that may be in a data set response

FIG. 17 shows an example of a request for a set of instances from person

FIG. 18 shows an example of contents for the religion object

FIG. 19 shows an example of the response from the request in FIG. 17

FIG. 20 shows the abstract data model example in FIG. 2 elaborated to illustrate views

FIG. 21 shows a data-set description that accesses persons who are for example, Muslim and the persons advanced skills

FIG. 22 shows the list of available query operators for a filter in a particular embodiment of the invention

FIG. 23 shows an example of a parameterized view

FIG. 24 shows an example of a data-set description with a parameterized view

FIG. 25 shows an example a request to a data-set with a parameterized view

FIG. 26 shows an example of a modification of the example in FIG. 2 to make the link to religion bi-directional

FIG. 27 shows an example of a modification of the abstract data model shown in FIG. 2 to include a multi-valued link

FIG. 28 shows an abstract data model illustrating a temporary link between person and address

FIG. 29 shows an abstract data model for a time table illustrating a many way link

FIG. 30 shows an abstract data model for family tree illustrating a self link

FIG. 31 shows a banking example of an abstract data model illustrating a link to a list

FIG. 32 shows an abstract data model illustrating a view of people who have at least one advanced skill

FIG. 33 shows an example of an internal event handler for a banking abstract data model

FIG. 34 shows an example of a calculated item involving a view

FIG. 35 shows an example of an abstract data model for a purchase order

FIG. 36 shows an example of a partial data entry screen for purchase order

FIG. 37 shows an example of a request involving a partial data read

### DETAILED DESCRIPTION OF THE INVENTION

A method which includes automatically building and maintaining an optimized data store and automatically building and maintaining optimized programming code to allow access to and update of the data in the data store is described. In the following description, for purposes of explanation, numerous specific details are set forth in order to provide a thorough understanding of the present invention. It will be evident, however, to one skilled in the art that the present invention may be practiced without these specific details.

The Network Environment

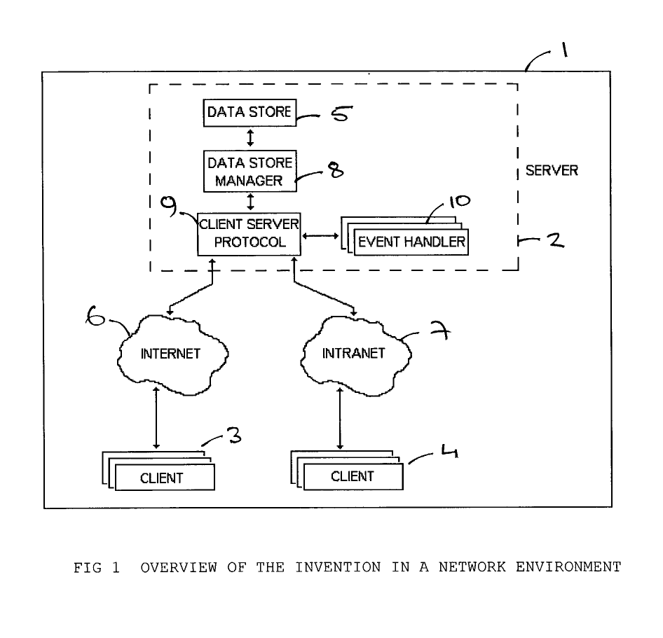

FIG. 1 is a diagrammatic representation of a network, designated generally at 1, within which the present invention may be implemented. The network 1 includes a single server 2 that hosts clients 3 and clients 4 and a data store 5. The data store 5 comprises a system that is capable of storing, retrieving and manipulating data. In one embodiment of the invention the data store 5 may comprise a Structured Query Language relational database such as SQL Server from Microsoft Corp. of Redmond, Washington State, or an Oracle 9i product from Oracle Corporation of Redwood Shores, Calif. In another embodiment of the invention the data store 5 may comprise an XML Repository such as Tamino XML Server from SoftwareAG of Darmstadt, Germany or the XIS XML database from excelon Corporation of Burlington, Massachusetts. Other embodiments of the data store 5 are possible.

Clients communicate with the DATA STORE MANAGER 8 utilizing a CLIENT SERVER PROTOCOL 9. The DATA STORE MANAGER 8 is shown to be accessible by CLIENTS 4 via an INTRANET 7 and by CLIENTS 3 via the INTERNET 6. The DATA STORE MANAGER 8 may also be accessible by a client resident on the SERVER 2. In one embodiment of the invention, each of the CLIENTS 3 and 4 comprises a browser, such as the Navigator browser from Netscape Communications Corp. of Mountain View, Calif. or the Internet Explorer (‘IE’) browser from Microsoft Corp.

An alternative network configuration within which the present invention may be implemented could involve having the DATA STORE 5 and DATA STORE MANAGER 8 residing on different physical servers.

According to the invention, the DATA STORE MANAGER 8 provides a method for the definition and update of a data management application using abstract objects. Such applications include convention GUI applications, web enabled data management applications, and other mechanisms for manipulating data. Data management applications are also referred to as ‘Apps’ in this specification. The DATA STORE MANAGER 8 employs the abstract objects thus produced to automatically build a physical DATA STORE 5. The DATA STORE MANAGER 8 also automatically builds and maintains programming code optimized for each instance to allow access to and update of the data in the DATA STORE 5.

Definition of the Abstract Objects and their Relationships

An abstract object model used by the data store manager 8 allows for objects to be both internally hierarchical and also have the ability to refer to each other relationally. This allows the abstract object model to be sufficiently expressive to describe real world situations. Such a real world description only describes real world items. Internal implementation details are not required.

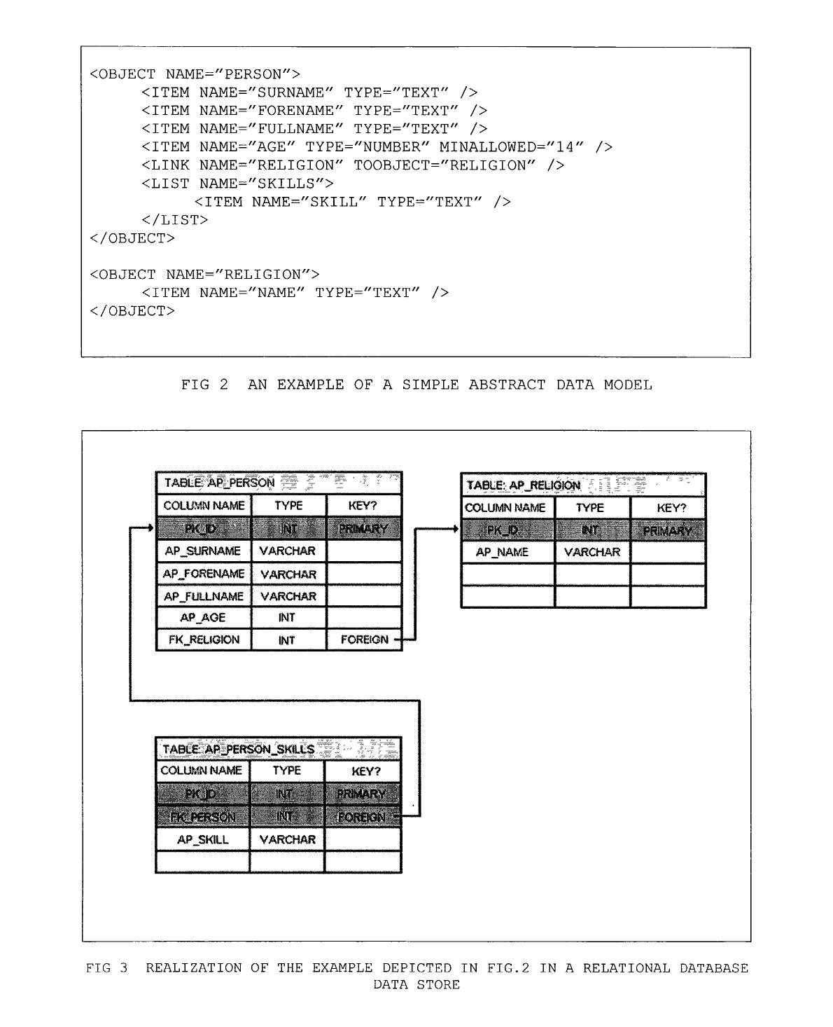

A simple example of an abstract data model employing abstract data objects (‘OBJECTS’) is shown in FIG. 2. A preferred embodiment of the invention includes a graphical user interface (‘GUI’) abstract object model editor which produces the Object descriptions required by the DATA STORE MANAGER 8 formatted as XML.

Realization of the Abstract Description on the Physical Data Store

When an abstract object model is created or modified, the DATA STORE MANAGER 8 realizes this model on a physical data store, including for example, a SQL database or an XML repository.

During this realization process additional implementation details may be added as required. FIG. 3 shows how the abstract data model depicted in FIG. 2 would be realized in a SQL database DATA STORE 5. The additional implementation details handled by the DATA STORE MANAGER 8 include columns to support PRIMARY and FOREIGN keys, the keys themselves, and indexes as required, to optimize performance. Because the tables in a SQL database DATA STORE 5 are non-hierarchical in nature, lists in the abstract data model may be realized as separate related tables. Implementations for other types of DATA STORE 5 such as an XML repository may not have this requirement.

A Screen Designer Automatically Maintains Data Set Descriptions along with a Screen Layout Design (Bound Elements)

An implementation of this invention will normally include some form of user screen (‘Screen’) designer. Different implementations are possible to target different types of Screen including forms in a conventional non web App, web pages in a web App and other forms of data collection and modelling.

Typically a Screen designer allows a Screen to be assembled using drag and drop operations similar to the dragging and dropping of files and folders in the Microsoft Windows Explorer. To facilitate this, it is common to provide an explorer for the abstract data model. Such an explorer allows the user to view the items available in each Object as well as drill across any links to see the items in related Objects. Opening a list or drilling across a link looks similar to opening a folder in Microsoft Windows Explorer. When an item is selected, elements attached to that item are then available to drag and drop onto the Screen being designed.

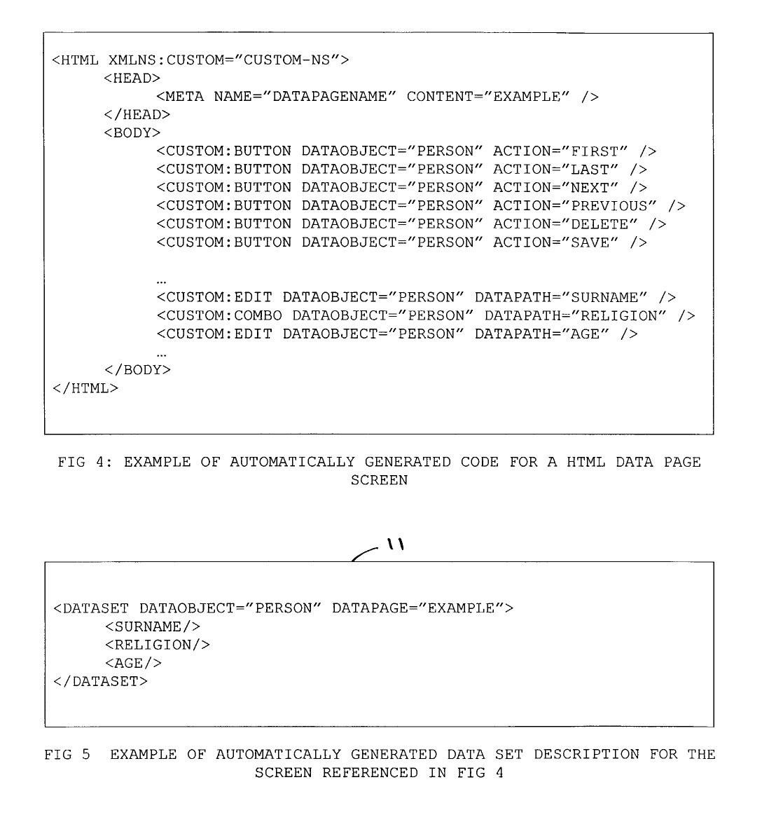

FIG. 4 gives an example of the HTML code for a Screen that is automatically produced by such a designer in the case where web pages are being designed. In a preferred embodiment, when ELEMENTS are dropped on the web page they will already have attributes DATAOBJECT and DATAPATH indicating the part of the abstract data model to which they are attached. The data-path is a key element in the invention and may contain an entire path through the abstract data model, thereby defining a precise binding between elements on the web page and items within the abstract data model. This embodiment is described in more detail later in the specification.

In another example of bound elements, FIG. 4 includes BUTTON elements that have been dragged onto a web page. Each BUTTON has an action attribute indicating the action that is invoked on the object when they are pressed in the GUI.

In an embodiment of the invention, when a Screen is saved, the DATAOBJECT and DATAPATH attributes are used to assemble one or more data-set descriptions. A data set indicates a subset of the entire abstract data model that is required for the current usage. This usage could include supporting data entry, reporting on a Screen, providing data to an event handler and allowing data to be updated from an event handler.

The Screen in FIG. 4 would result in the creation of a DATASET DSCRIPTION 11 shown in FIG. 5.

Automatic Code Generator that generates Data-tier Specific Code for each Data-set, Optimizing Server Performance and Minimizing Network Traffic (Data on Demand)

When a Screen is saved, the associated data set descriptions are used by the DATA STORE MANAGER 8 to automatically generate the code required to execute the various actions that are available for the data-set.

It is a particular feature of the invention that this code is specifically generated for each data-set. The code being specifically generated for a given data-set ensures that only items required by that data-set are transferred from the server. Only the data demanded is transferred. (‘Data on Demand’). The performance of each Screen is maximised by Data on Demand in a number of fashions, including minimizing server loading and minimizing network traffic.

In an embodiment of the invention, the code that is automatically generated to implement a data-set will depend on the particular data store being used. For example SQL may be used to implement a data-set on a relational database data store 5. XSLT (Extensible Stylesheet Language Transformation) or XQuery may be used to implement a data-set on an XML repository DATA STORE 5.

Client Server Protocol Provides Optimized Access to the Actions Available for a Data-set (Atomic Commit).

Once a data-set has been implemented and data store specific code generated by the DATA STORE MANAGER 8, the code is available for use. Such use may typically be triggered automatically by using the Screen, whose design caused the DATA STORE MANAGER 8, to generate the data-set description specific to that particular Screen.

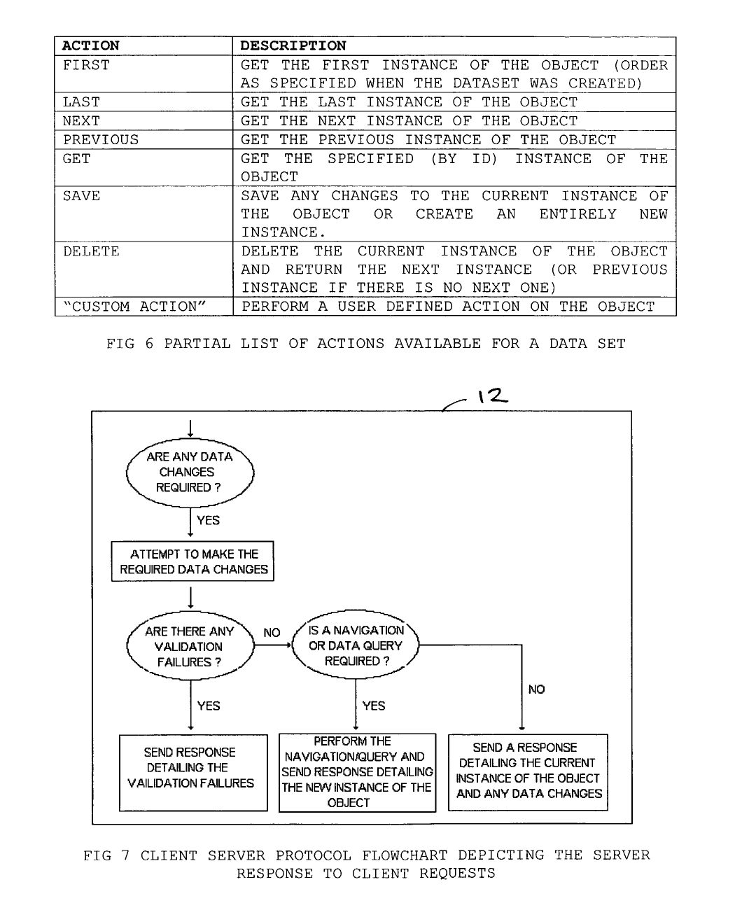

A REQUEST-RESPONSE style PROTOCOL 12 may be employed by the client Screen to interact with the DATA STORE 5 via the DATASET, as outlined in FIG. 7. In order to minimize server round-trips this protocol may include an implied save action as well as an explicit action, typically involving navigation. A list of possible actions available for a data set is shown in FIG. 6. When data is being saved to the server, the existence of an ID ELEMENT indicates an instance being updated. The absence of an ID ELEMENT indicates an instance being inserted.

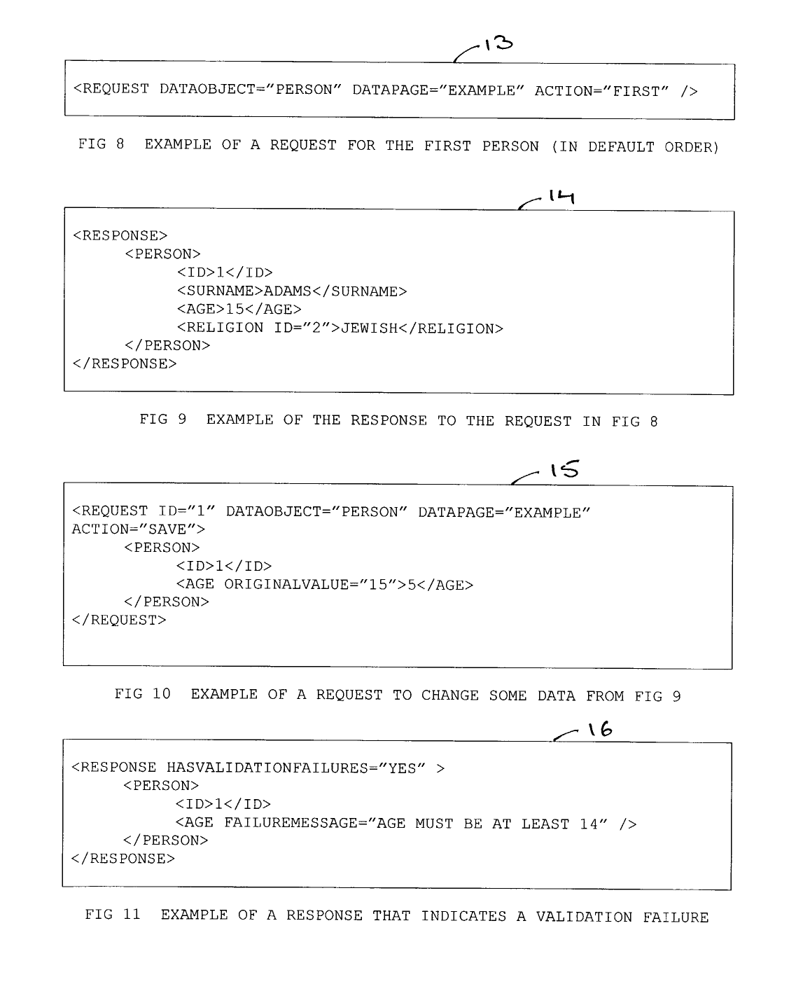

The PROTOCOL 12 is covered in more detail later in this specification. The following are included by way of example. FIG 8 shows an example of a REQUEST 13 for the first instance of a PERSON in an OBJECT entitled PERSON (in default order).

FIG. 9 shows a typical PROTOCOL 12 RESPONSE 14 to the REQUEST 13. Note that any items not specified in the data-set are omitted from the response. If required the response may include related items in other Objects.

FIG. 10 shows an example of a PROTOCOL 12 REQUEST 15 to change the AGE of a PERSON in the PERSON OBJECT of FIG. 8.

In a particular embodiment of the invention, the PROTOCOL 12 may cause all data changes made by a user to be buffered on the client until the user presses a save button. These changes (which may include items from lists) may then be uploaded to the server via a single request message. The server then may commit all the requested changes or return a response listing validation failures. This is an atomic commit process of the PROTOCOL 12, whereby either all the requested changes are made to the DATA STORE 5, or no changes are made to the DATA STORE 5.

FIG. 10 shows an example, whereby the PROTOCOL 12 REQUEST 15 would attempt to reduce the AGE parameter below the AGE minimum (as specified in the abstract data model shown in FIG. 2). The result is conveyed in a RESPONSE 16 indicating a validation failure as shown in FIG. 11.

In the event of attempted data changes resulting in several validation failures, the DATA STORE MANAGER 8 may cause these validation failures to be listed in a single response to minimize server round trips. A typical client implementation may handle such a situation by changing, for example, the background colour of the appropriate elements to red and displaying a message indicating the validation error message for the currently focused element.

In a particular embodiment of the invention, a plurality of different constraints defined in the abstract data model may trigger validation failures or advisory validation warnings. Furthermore, the DATA STORE MANAGER 8 will generate a validation error if another user has already changed a data item for which an update is being attempted.

When no validation failures occur and the data is committed, a response occurs listing the data (including changes) for the current instance of the object if an explicit save action was requested. Alternatively if another explicit action was requested such as NEXT, the PROTOCOL 12 response may list the data for the requested instance of the Object.

Explicitly Defining Data-sets

In an embodiment of the invention, a mechanism for explicitly defining data-sets is available. The data-sets may then allow access to specific portions of the DATA STORE 5, for custom code event handlers.

In practice, it may be desirable to augment the code automatically generated for a data-set with custom event handlers. These handlers can be attached to various events, including when a data change is made to an object instance or list (ONUPDATE), when a new object instance or list entry is created (ONINSERT), when an object instance or list entry is deleted (ONDELETE) and when an object instance or list entry is read (ONREAD).

The code in such a handler interacts with the DATA STORE 5, via a data-set. In this case the data-set may be created explicitly by the event handler writer, rather than being generated implicitly by the DATA STORE MANAGER 8 when a Screen is saved.

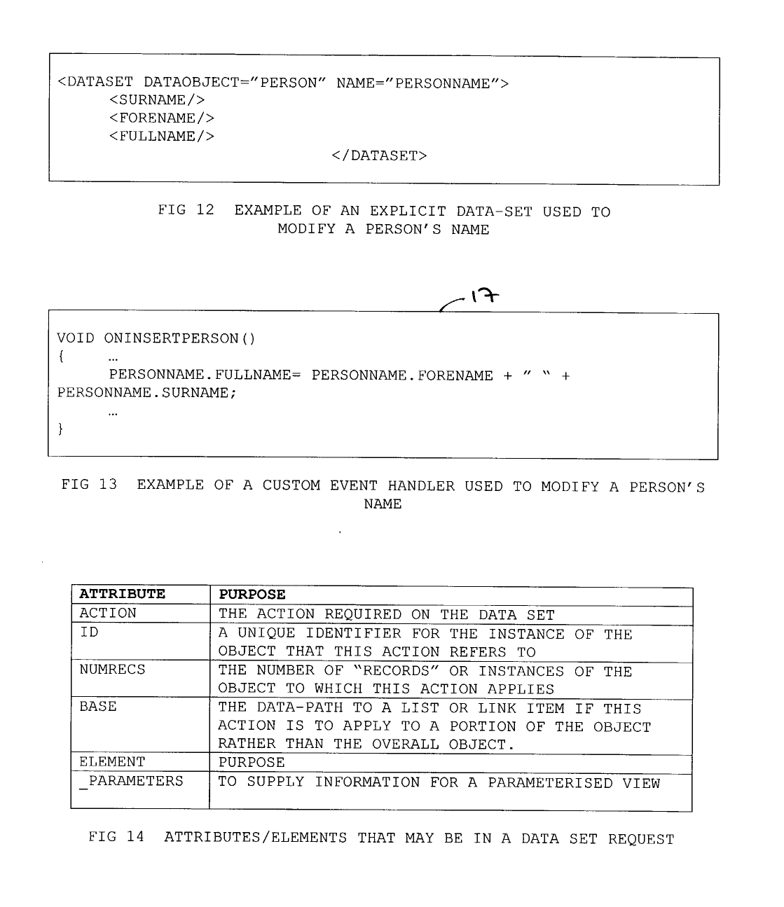

As a simple example, let us assume that a FULLNAME item should be automatically filled when an instance of a PERSON is inserted. An explicit DATASET would be created as shown in FIG. 12 (typically via a front-end). An example of the custom code EVENT HANDLER 17 to update a Person's full name is shown in FIG. 13. This example indicates an external event handler. It is also possible to define the EVENT HANDLER 17, within the abstract data model using a built in expression system, described later. In an embodiment of the invention, a calculated item (described later) could be employed instead of writing a custom EVENT HANDLER 17.

Event handlers execute in the context of the server transaction that occurs from the original client request. It is possible for Event handlers to generate validation errors explicitly where appropriate. Event handlers adhere to the atomic commit process whereby either all changes (from event handlers and the original client request) take place to the DATA STORE 5, or no changes take place.

Client Server Protocol

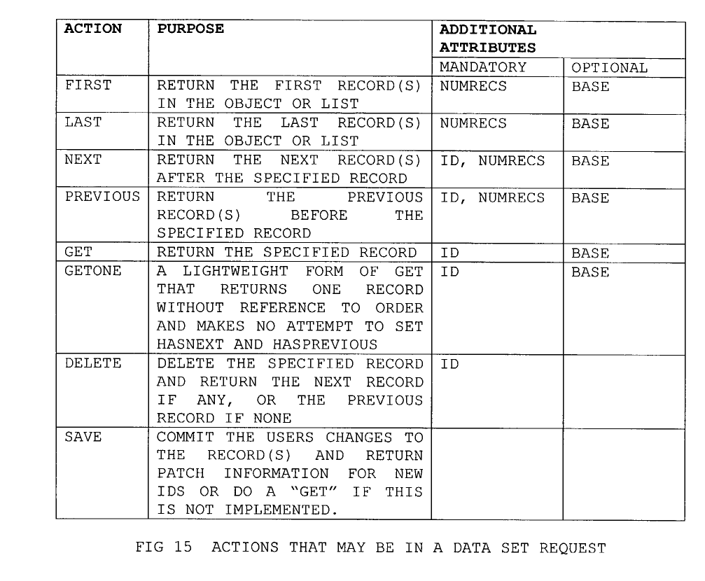

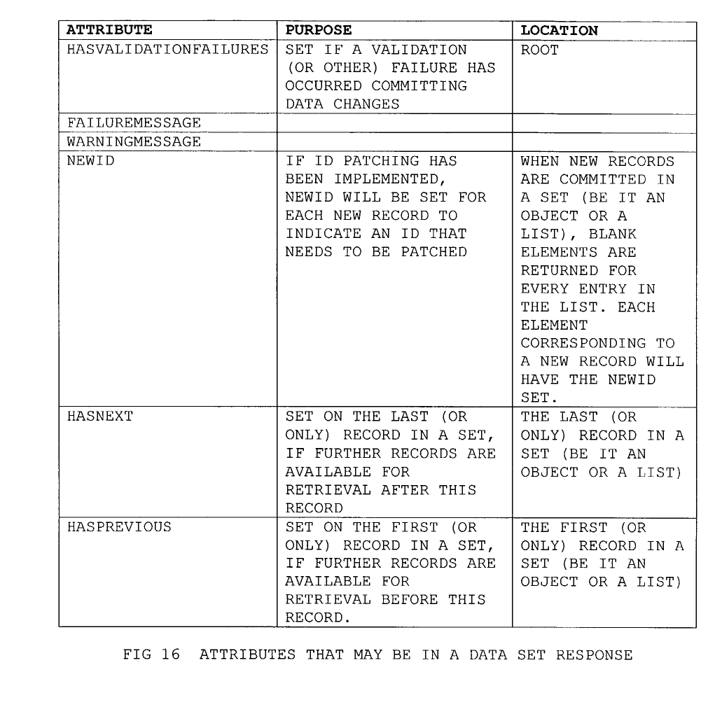

A further description an embodiment of the PROTOCOL 12 is given in the following figures. FIG. 14 includes some ATTRIBUTES and ELEMENTS that may define a data-set request. FIG. 15 includes some ACTIONS that occur in a DATASET REQUEST and the ATTRIBUTES that may apply to each action. FIG. 16 includes some ATTRIBUTES that may occur in a DATASET RESPONSE.

An embodiment of the invention may include additional features of the PROTOCOL 12 including views, links, data-paths, expressions and partial reads of which examples are listed in following figures.

View

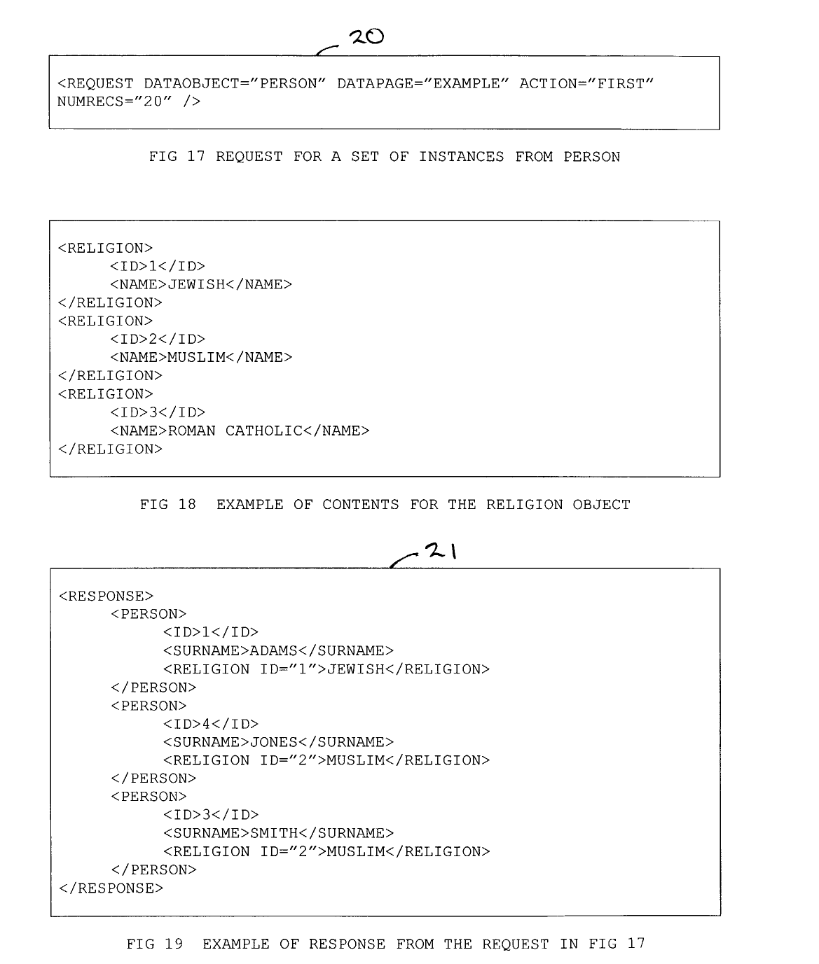

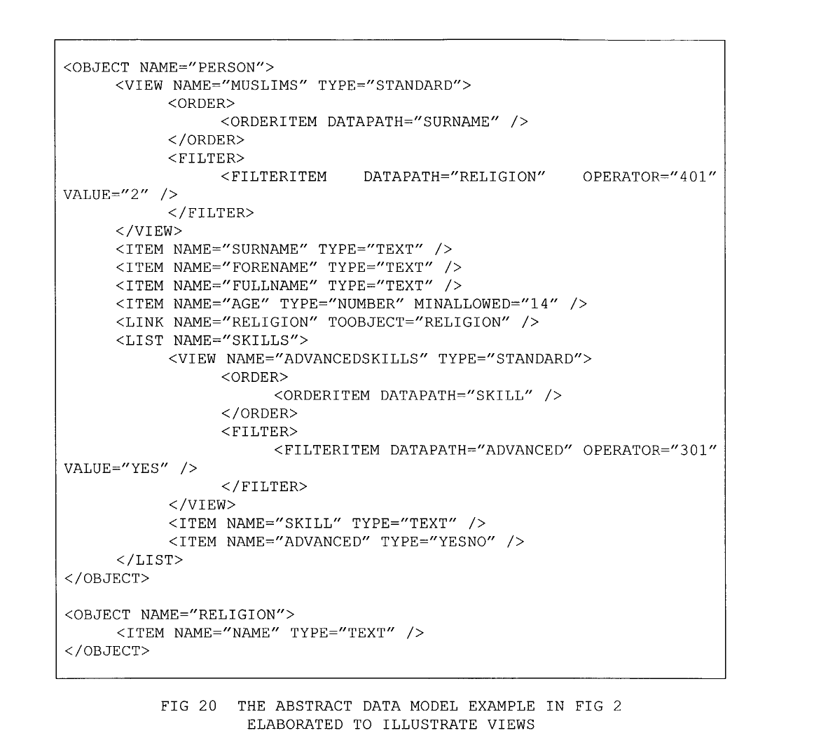

Normally when data is requested from a data-set all instances of the object are returned (up to the specified number of records) ordered by the first non system item. As an example, consider the REQUEST 20 shown in FIG. 17. If we assume the contents of the RELIGION OBJECT are as shown in FIG. 18, then an example of a RESPONSE 21 to this REQUEST is shown in FIG. 19. In this example, all the existing instances (3) are returned ordered by SURNAME.

To get more controlled access to the instances of an Object or list, a view is employed. Views are created as part of the abstract object model. Various types of view may exist including an analysis view that specifies dimensions and measures for online analytical processing or OLAP style data cubes and a standard view that specifies a filter and an order.

As an example of the standard view, consider FIG. 20. This elaborates the simple abstract data model example from FIG. 2 to add two views. The “MUSLIMS” view which accesses instances of the OBJECT PERSON that are MUSLIMS in SURNAME order. The ADVANCEDSKILLS view which access instances of SKILLS that are ADVANCED in SKILL order.

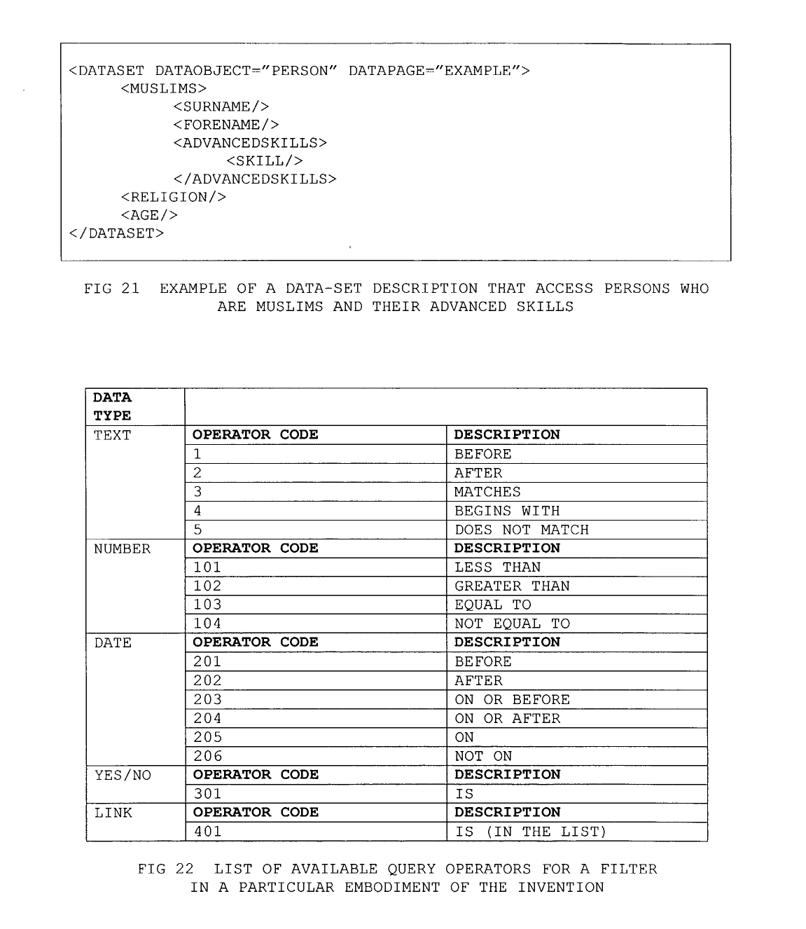

An example of a data-set description to access PERSONS who are MUSLIMS and their ADVANCED SKILLS is shown in FIG. 21.

FIG. 22 includes an example of a set of QUERY OPERATORS for a FILTER. More sophisticated filters are possible by having a more elaborate data-path. The expressive power of the DATAPATH attribute is covered later.

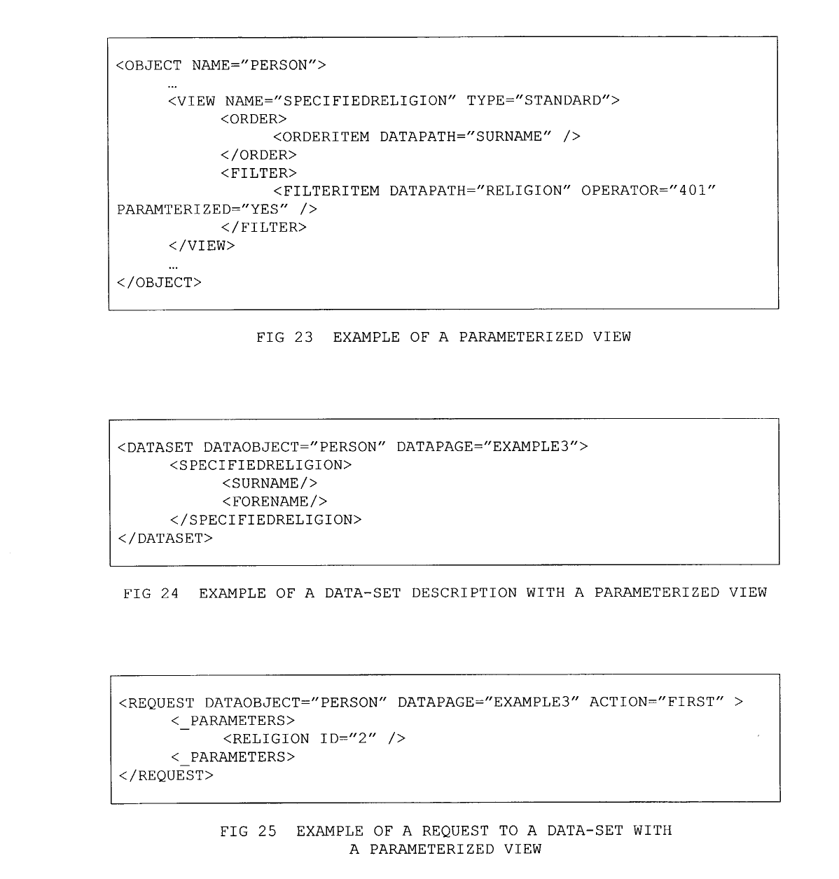

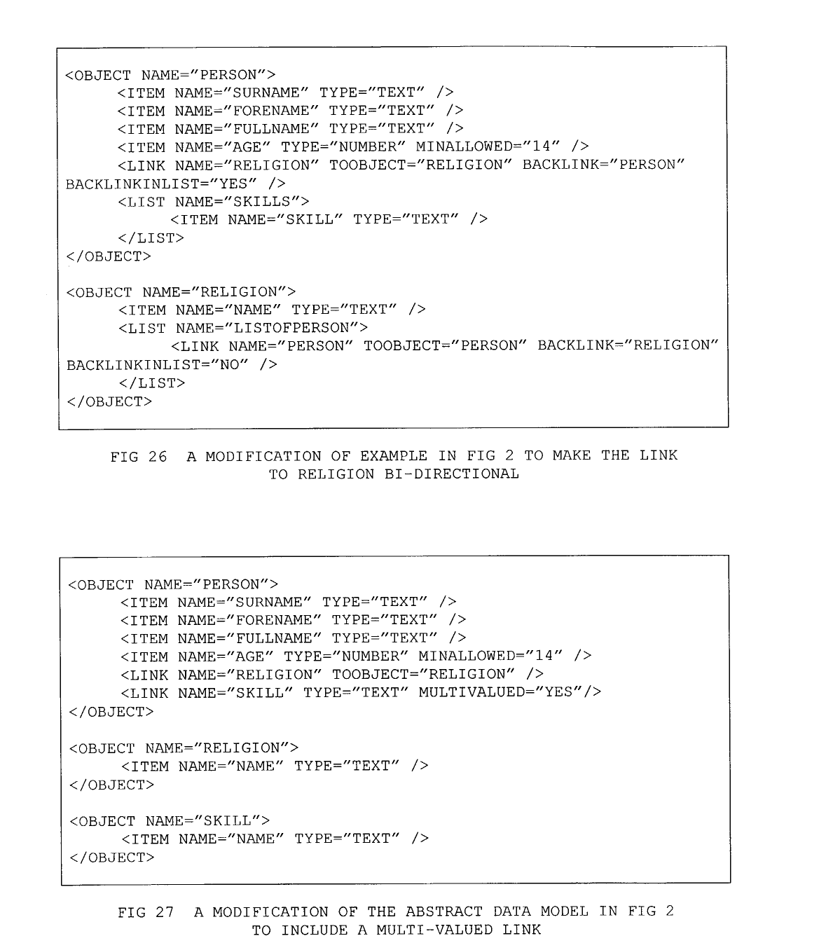

Often a view may be required where search information can be supplied when the data-set is actually used. Such a view is called a PARAMETERISED VIEW. An example of a parameterized view is given in FIG. 23. This illustrates an additional view for the PERSON OBJECT in the abstract data model that allows the person's RELIGION to be specified when data is requested from the data-set. An example of such a data-set description is show in FIG. 24. An example of a REQUEST for data from this DATASET is shown in FIG. 25.

Link

The most basic of Object links in the abstract data model is the single direction single-value permanent link between two OBJECTs. This is illustrated by the link from PERSON to RELIGION which is shown by example in FIG. 2. The DATA STORE MANAGER 8 provides for a plurality of types of link, including BACK LINKS, MULTI-VALUED LINKS, TEMPORARY LINKS, MANY WAY LINKS, SELF LINKS and LINKS to a LIST.

Back Link

In certain cases it is desirable to be able to access the information defined by a link in the reverse direction. An example of this is if we require a data-set that lists all the PEOPLE with a specified RELIGION. To do this, the abstract data model from FIG. 2 may be modified as shown in FIG. 26. In many cases the BACK LINK will be inside a LIST to allow for a MANY to ONE relationship. In some cases the LINK may be inside a LIST in both OBJECTs to implement a MANY to MANY relationship.

Multi-valued Link

In most cases a LINK is single valued. It can only be set to a single instance of the OBJECT being linked to. However it is possible to specify that a LINK is MULTI-VALUED in which case the user will see a comma separated list of values. Typically the user interface will include a multiple selection drop down list combo element to allow the data for such a link to be updated. The example in FIG. 2 has been modified to provide an example of a MULTIVALUED-LINK in FIG. 27. A superfluous LIST has been removed and the LINK to the new SKILL OBJECT has been specified to be MULTI-VALUED. This allows the user to specify a list of skills for each PERSON.

Temporary Link

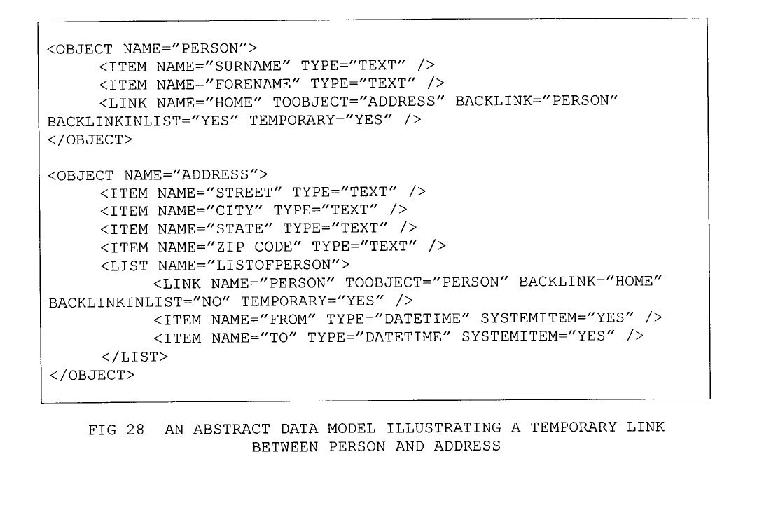

Typically the association between OBJECTs in a LINK is permanent. However it may be desirable to specify a LINK where the association is TEMPORARY and a history of different associations may be required. When this is done, additional system items are added to specify the duration of the LINK. The original abstract data model in FIG. 2 has been modified to demonstrate a TEMPORARY LINK between PERSON and ADDRESS in FIG. 28.

Many Way Link

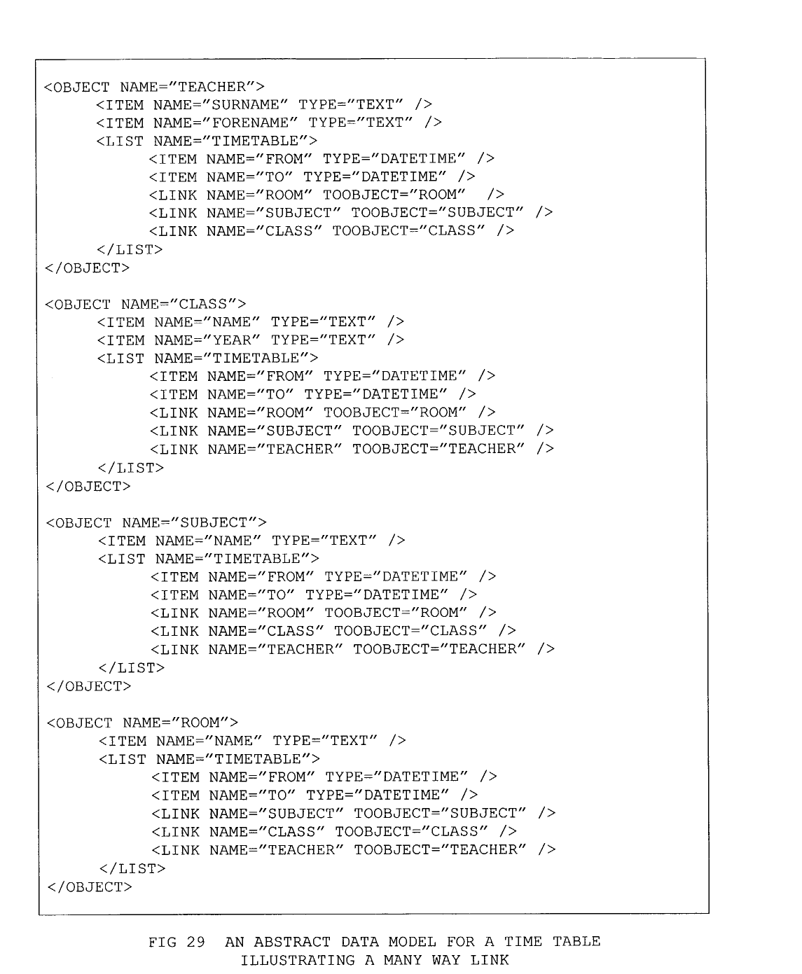

Typically a link specifies an association between two OBJECTs. However in certain cases an association may be desirable between more than two OBJECTS. An example of an abstract data model for a time table is given in FIG. 29. This illustrates a MANY WAY LINK between four OBJECTs—TEACHER, CLASS, SUBJECT and ROOM. In the case of MANY WAY LINKS, the LIST within which the LINK is embedded is shared between all OBJECTs involved in the LINK.

Self Link

Typically there are at least two distinct OBJECTs involved in a LINK. However it may be desirable for an OBJECT to LINK to itself. An example of this is demonstrated in FIG. 30 which illustrates the PERSON OBJECT linking to itself in order to construct a family tree.

Link to a List

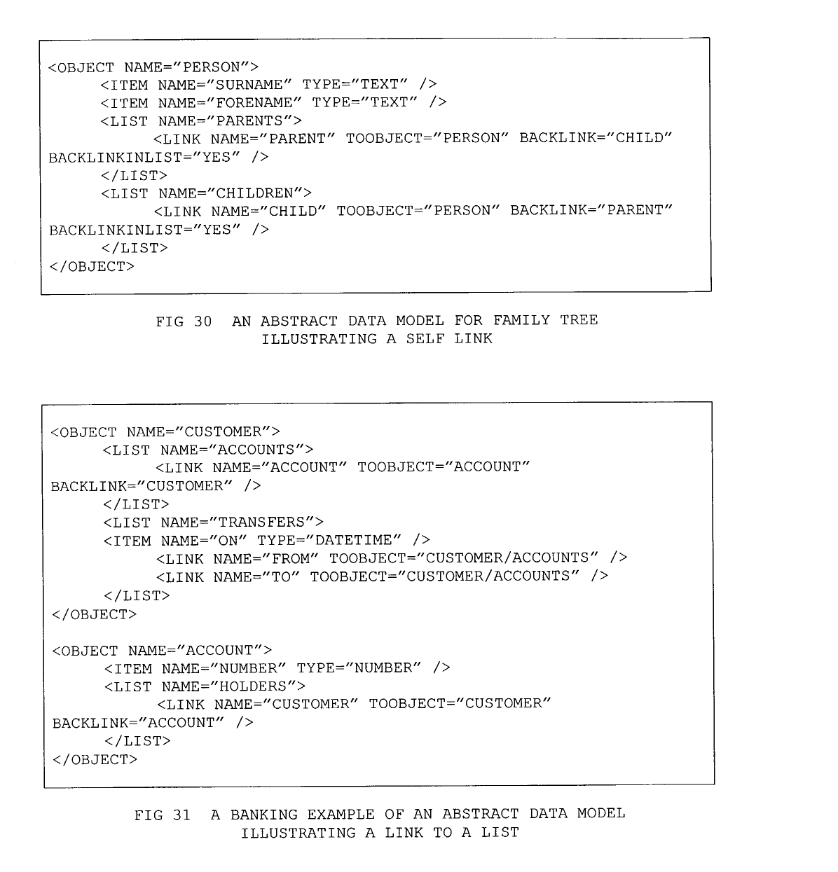

Typically a LINK links to a whole OBJECT. However it may be desirable where necessary to link to a LIST within an OBJECT. A Banking industry example illustrates this concept in FIG. 31. Here a CUSTOMER has a LIST of ACCOUNTs and also a LIST of TRANSFERs that have taken place. It should only be possible to perform transfers between a CUSTOMER's own ACCOUNTS. Therefore the FROM and TO LINKs don't link to the ACCOUNT OBJECT as this would allow a transfer to be specified involving any account at the bank. Instead the LINK is to the ACCOUNTS LIST within CUSTOMER constraining FROM and TO so that each is forced to be one of the CUSTOMER's own ACCOUNTS. In order to specify this LINK, a two section DATAPATH is specified in the TOOBJECT attribute for the FROM and TO items.

Data-path

A key element of this invention and its novelty over prior art is the method of data-paths. In an embodiment of the invention, a DATAPATH may refer not just to an item in an Object, but also to the route taken through the data store 5 in order to access that item. A data-path consists of one or more sections each separated by “/”. Each section contains a name that can reference parts of the abstract data model including: simple items, views, lists and links.

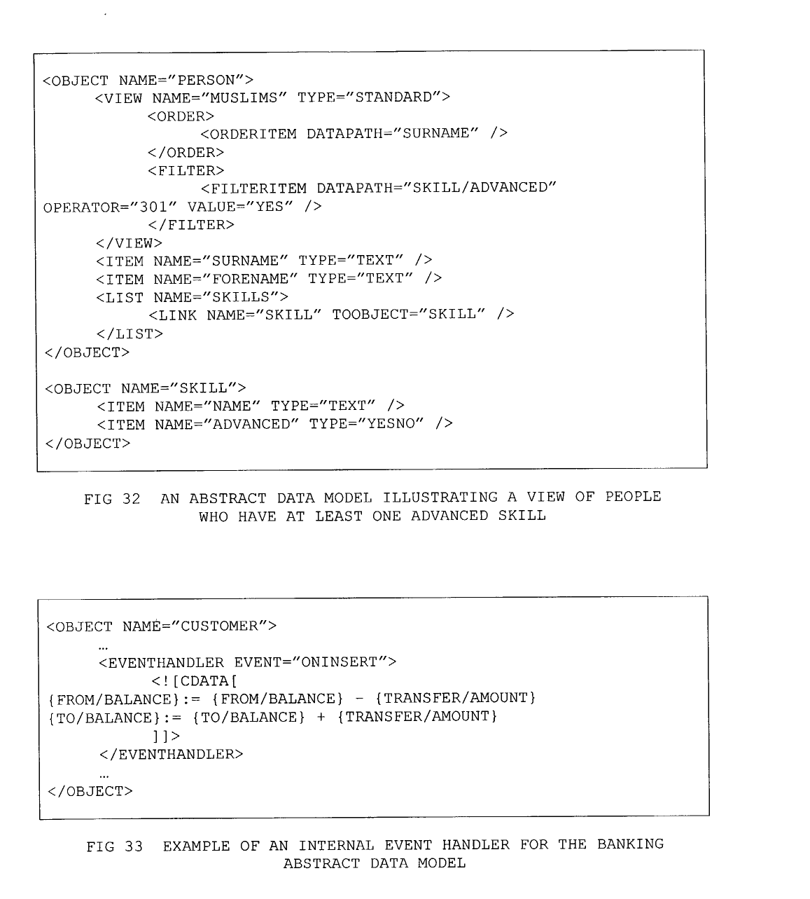

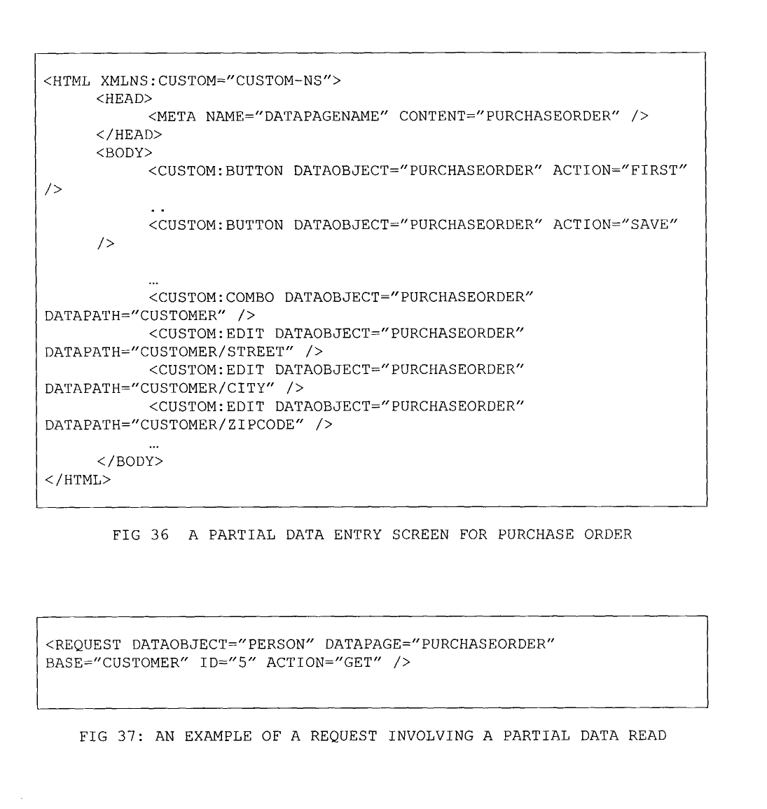

It is a feature of this invention that the interpretation of the DATAPATH by the DATA STORE MANAGER 8 provides precise control for the DATA that is being specified. Data-paths can be used in a number of ways both within the abstract data model and in screen definition including the TOOBJECT ATTRIBUTE of a LINK (See FIG. 31), the DATAPATH ATTRIBUTE in a FILTERITEM ELEMENT (See FIG. 32), and the DATAPATH ATTRIBUTE in any BOUND ELEMENT on the CLIENT (See FIG. 36)

Expressions

In an embodiment of the invention, data-paths may be utilized in expressions enclosed in { . . . } brackets. A typical embodiment of the invention will include expressions with a flexibility similar to those found in popular spread-sheets such as Microsoft Excel TM. Where spread-sheet formulae refer to cells, expressions in the DATA STORE MANAGER 8 use data-paths to refer to items.

Expressions may be used for a plurality of purposes within the DATA STORE MANAGER 8 including INTERNAL EVENT HANDLERS, CALCULATED ITEMS, the VALIDATIONEXPRESSION attribute, the WARNINGEXPRESSION ATTRIBUTE, the INVISIBLEWHEN ATTRIBUTE and the DISABLEDWHEN ATTRIBUTE.

Internal Event Handlers

An example of an external EVENT HANDLER is given by example in FIG. 13. It is also possible to define internal event handlers within the abstract data model. Consider the banking example in FIG. 32. Upon a TRANSFER RECORD being inserted, a side effect adjusting the balances of the appropriate accounts could be achieved with an EVENT HANDLER. To achieve this, the EVENT HANDLER shown in FIG. 33 can be added to the abstract data model as part of the CUSTOMER OBJECT. In a typical embodiment of the invention, the abstract data model may be described in a language such as Extensible Markup Language (XML), which is automatically produced by the a GUI abstract data model editor.

Calculated Items

Expressions can involve data-paths and it is therefore possible to specify CALCULATED ITEMS with expressions to reference data in many parts of the abstract data model including data in a view, data across a link and data that has itself being calculated.

Referencing Data in a View

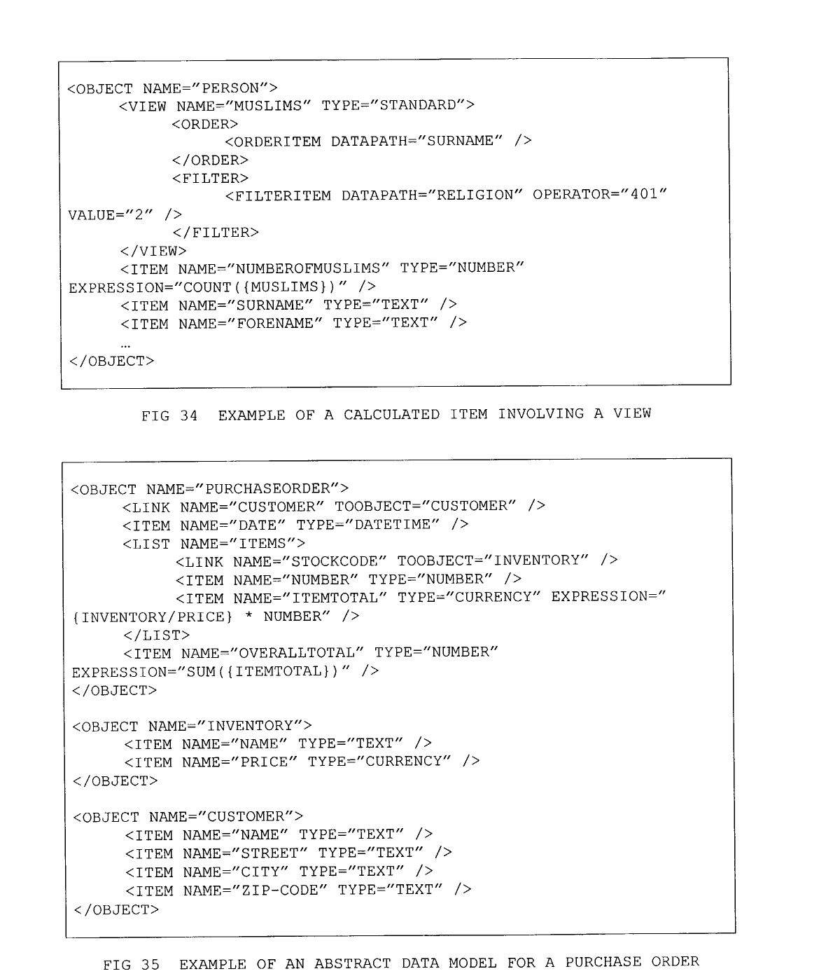

FIG. 34 shows an example of reference to data in a view. Modifying the abstract data model from FIG. 20, we can add a CALCULATED ITEM: NUMBEROFMUSLIMS to count the number of instances of the MUSLIMS view.

Reference data across a link and reference data that has itself being calculated

These are illustrated by the abstract data model of a PURCHASE ORDER as shown in FIG. 35. In this example ITEMTOTAL references data across a LINK, namely the PRICE of an ITEM in INVENTORY. The OVERALLTOTAL item references data that has itself been calculated namely ITEMTOTAL.

Partial Reads

In a particular embodiment of the invention, it may be desirable for the client server PROTOCOL 12 to support partial updates to a Screen on the client. This may be achieved using the BASE attribute described in FIG. 14. For example using the PURCHASEORDER abstract data model as shown in FIG. 35, the code to produce a partial data entry Screen is shown in FIG. 36. When the user chooses CUSTOMER from the drop down combo, the address for that CUSTOMER will update automatically in the appropriate elements. An example of the server REQUEST 13 resulting from such an action is shown in FIG. 37.

Additional Features of the Invention

The features that are defined in the abstract data model are not limited to the foregoing, and may include the following.

Attributes to implement a role based security model to control access to and update of items and Objects.

Additional validation attributes beyond the MINALLOWED illustrated in FIG. 2 including REQUIRED to flag an item as mandatory, MAXALLOWED to specify the maximum allowed value, VALIDATIONEXPRESSION to specify a mandatory constraint as an expression that may involve data-paths to other objects, VALIDATIONMESSAGE to specify an item specific error message when a validation failure occurs, WARNINGEXPRESSION to specify an advisory constraint where the user's attention should be drawn but where a commit can still take place at his/her discretion, ALLOWEDCHARACTERS to specify a regular expression for the allowed characters in an item, INVISIBLEWHEN to specify an expression to control the visibility of elements bound to an item and DISABLEDWHEN to specify an expression to control the read-only status of elements bound to an item.

Thus, a method of automatically building and maintaining an optimized data store which includes means for the definition of abstract objects and their relationships, means for realization of the abstract description in a physical data store, a user screen designer that automatically maintains data set descriptions and the actual user screen design, a method for automatically building and maintaining optimized programming code to allow access to and update of the data in the data store which includes means for the automatic generation of code to generate data store specific code for each data set while optimizing server performance and minimizing network traffic, a client server protocol that allows optimized access to the actions available for a data set and a mechanism for explicitly defining data sets whereby these data sets can allow access to specific portions of the data store from custom code event handlers has been described. Although the present invention has been described with reference to specific exemplary embodiments, it will be evident that various modifications and changes may be made to these embodiments without departing from the broader spirit and scope of the invention. Accordingly, the specification and drawings are to be regarded in an illustrative rather than a restrictive sense.

What is claimed is:

1. A method comprising:
the definition of an abstract data model to describe real world entities and their relationships

2. An apparatus comprising means for the definition of the optimized abstract data model.

3. An apparatus constructing a physical data store to conform to the abstract data model;
automatically optimizing the data store for performance.

4. A method comprising:
means to generate a data set description from a screen layout description;
automatically specifying which parts of the data-store are required when the screen is used.

5. An apparatus comprising means to generate data store specific code for an individual data set,
automatically producing appropriate code for a given physical data store,
automatically producing optimized code for the implementation of a data set,
automatically producing optimized code for each specific utilization of the data-store.

6. Claim 6 is intentionally blank.

7. The method of claim 5 wherein the data store utilization specific code optimizes performance,
Automatically minimizing server loading;
Automatically minimizing network traffic.

8. A method comprising a client server protocol,
Automatically minimizing server loading;
Automatically minimizing network traffic;
Automatically increasing responsiveness of the client.

9. A method of claim 1 wherein data within the abstract data model can be identified using a data-path automatically identifying a route through the abstract data model to access the data.

10. A method of claim 1 wherein data within an object in the abstract data-model can be identified using a view,
Specifying appropriate access to aggregate data
Specifying selective access to filtered data.

11. The method of claim 1 wherein an object within the abstract data model may be connected by a plurality of links to itself and other objects.

12. The method of claim 11 wherein the connection is a single direction single-value permanent link between two objects.

13. The method of claim 11 wherein the connection provides a link in the reverse direction between two objects.

14. The method of claim 11 wherein the connection is a multi valued link.

15. The method of claim 11 wherein the connection is temporary.

16. The method of claim 11 wherein the connection provides a link between more than two objects.

17. The method of claim 11 wherein the connection provides a link to a list within an object.

18. The method of claim 9 wherein a data path may refer to an item in an object and to the route taken to access that item within the abstract data model.

19. The method of claim 9 wherein expressions may be defined to perform operations on items in objects within the abstract data model.

20. The method of claim 9 wherein event handlers may be defined within the abstract data model.

21. The method of claim 9 wherein custom event handlers may be defined externally to operate on data within the abstract data model and data outside the abstract data model.

22. The method of claim 9 wherein partial updates are provided to a user page on a client.

23. A method comprising custom attributes to implement a role based security model to control access to and update of items in the abstract object model.

24. A computer system comprising:
a processor; and
a memory coupled with the processor to store a data store having a database structure;
the processor to generate an optimized data store;
the processor to generate optimized programming code to provide access to the optimized data store and optimized programming code to update data in the optimized data store.

25. A computer-readable medium having instructions stored thereon that, when executed by a computer, cause the computer to:
generate an optimized data store;
generate optimized programming code to provide access to the optimized data store; and
generate optimized programming code to update data in the optimized data store.
